(19) United States
(12) Patent Application Publication
(10) Pub. No.: US 2011/0092073 A1
(43) Pub. Date: Apr. 21, 2011

(54) PLASMA PROCESSING APPARATUS, PLASMA PROCESSING METHOD, AND METHOD FOR MANUFACTURING ELECTRONIC DEVICE

(75) Inventors: Hideyuki Nitta, Kanagawa-ken (JP); Takashi Hosono, Kanagawa-ken (JP); Takefumi Minato, Kanagawa-ken (JP); Yoshihisa Kase, Kanagawa-ken (JP); Makoto Muto, Kanagawa-ken (JP)

(73) Assignee: SHIBAURA MECHATRONICS CORPORATION, Yokohama-shi, Kanagawa-ken (JP)

(21) Appl. No.: 12/996,878

(22) PCT Filed: Jun. 3, 2009
(86) PCT No.: PCT/JP2009/060124

§ 371 Date: Dec. 8, 2010

(30) Foreign Application Priority Data
Jun. 13, 2008 (JP) 2008-155101

(51) Int. Cl. H01L 21/465; C23C 16/455; C23C 16/458; C23C 16/511; C23C 16/46; C23F 1/08; C23F 1/00

(52) U.S. Cl. 438/716; 118/723 MW; 156/345.33; 427/575; 216/69; 438/758; 257/E21.485

(57) ABSTRACT

A plasma processing apparatus includes: a processing container capable of maintaining an atmosphere having a pressure lower than atmospheric pressure; an evacuation unit reducing a pressure of an interior of the processing container; a gas introduction unit introducing a process gas to the interior of the processing container; a microwave introduction unit introducing a microwave to the interior of the processing container; and a lifter pin ascendably and descendably inserted through a placement platform provided in the interior of the processing container, an end surface of the lifter pin supporting an object to be processed, the object to be processed being supported by the lifter pin at a first position proximal to an upper surface of the placement platform when the microwave is introduced and plasma is ignited, the object to be processed being supported by the lifter pin at a second position after the plasma ignition, the second position being more distal to the placement platform than the first position.

### TECHNICAL FIELD

This invention relates to a plasma processing apparatus, a plasma processing method and a method for manufacturing an electronic device.

### BACKGROUND ART

Dry processes utilizing plasma are used practically in a wide range of technical fields such as the manufacturing of electronic devices, the surface curing of metal parts, the surface activation of plastic parts, non-chemical sterilization, etc. For example, various plasma processing such as ashing, dry etching, thin film deposition or surface modification, etc., are performed during the manufacturing of electronic devices such as semiconductor apparatuses and liquid crystal display apparatuses. Dry processes utilizing plasma have low costs, high speeds, and are advantageous also by reducing environmental pollution because chemicals are not used.

Various plasma processing apparatuses have been proposed to perform such plasma processing. A placement platform for placing an object to be processed (e.g., a semiconductor wafer, etc.) is provided in the processing container of such a plasma processing apparatus. Lifter pins for performing the delivery of the object to be processed are provided in the placement platform. Also, in some cases, a heater for heating the object to be processed is provided in the placement platform.

Here, technology for lifting the object to be processed from the upper surface of the placement platform by lifter pins and processing the object to be processed is known.

For example, in the case where plasma processing is performed in which the object to be processed is lifted from the upper surface of the placement platform by lifter pins, the object to be processed is lifted higher than the position of the delivery, and then plasma is generated (refer to JP-A 10-22276 (Kokai) (1998)).

In such a case, the microwave introduced into the processing container may be undesirably absorbed by the object to be processed and the ignition rate of the plasma may decrease in the case where the lift amount of the object to be processed is great and the object to be processed and the placement platform are too distal to each other.

Conversely, in the case where the lift amount of the object to be processed is low, the thermal effect from the heating unit provided in the placement platform becomes intense and in some cases, the object to be processed may undesirably be heated unnecessarily. Moreover, there is a risk that the processing speed may decrease, the uniformity in the processing surface may worsen, etc., and the controllability of the plasma processing may worsen because the object to be processed and the generated plasma are too distal to each other.

### PATENT CITATION 1

JP-A 10-22276 (1998)

### DISCLOSURE OF INVENTION

### Technical Problem

The invention provides a plasma processing apparatus, a plasma processing method, and a method for manufacturing an electronic device that can increase the ignition rate of plasma.

### Technical Solution

According to an aspect of the invention, there is provided a plasma processing apparatus, including: a processing container capable of maintaining an atmosphere having a pressure lower than atmospheric pressure; an evacuation unit reducing a pressure of an interior of the processing container; a gas introduction unit introducing a process gas to the interior of the processing container; a microwave introduction unit introducing a microwave to the interior of the processing container; and a lifter pin ascendably and descendably inserted through a placement platform provided in the interior of the processing container, an end surface of the lifter pin supporting an object to be processed, the object to be processed being supported by the lifter pin at a first position proximal to an upper surface of the placement platform when the microwave is introduced and plasma is ignited, the object to be processed being supported by the lifter pin at a second position after the plasma ignition, the second position being more distal to the placement platform than the first position.

According to another aspect of the invention, there is provided a plasma processing method, including: supporting an object to be processed by an end surface of a lifter pin ascendably and descendably inserted through a placement platform provided in an interior of a processing container; reducing a pressure of the interior of the processing container to less than atmospheric pressure; introducing a process gas to the interior of the processing container, introducing a microwave to the interior of the processing container, and initiating plasma; and performing a plasma processing of the object to be processed, the object to be processed being supported by the lifter pin at a first position proximal to an upper surface of the placement platform when igniting the plasma, the object to be processed being supported by the lifter pin at a second position after the plasma ignition, the second position being more distal to the placement platform than the first position.

According to still another aspect of the invention, there is provided a method for manufacturing an electronic device by performing a plasma processing of an object to be processed by using the plasma processing apparatus according to any one of claims 1-4.

### ADVANTAGEOUS EFFECTS

This invention provides a plasma processing apparatus, a plasma processing method and a method for manufacturing an electronic device.

### BRIEF DESCRIPTION OF DRAWINGS

FIG. 1 is a schematic view illustrating a plasma processing apparatus according to an embodiment of the invention.

FIG. 2 is a graph illustrating the relationship between the lift amount and the temperature of the object to be processed.

FIG. 3 is a graph illustrating the relationship between the lift amount of the object W to be processed and the ignition rate of the plasma.

FIG. 4 is a graph illustrating the temperature of the object to be processed during the plasma processing.

### BEST MODE FOR CARRYING OUT THE INVENTION

Embodiments of the invention will now be illustrated with reference to the drawings. Similar components in the drawings are marked with like reference numerals, and a detailed description is omitted as appropriate.

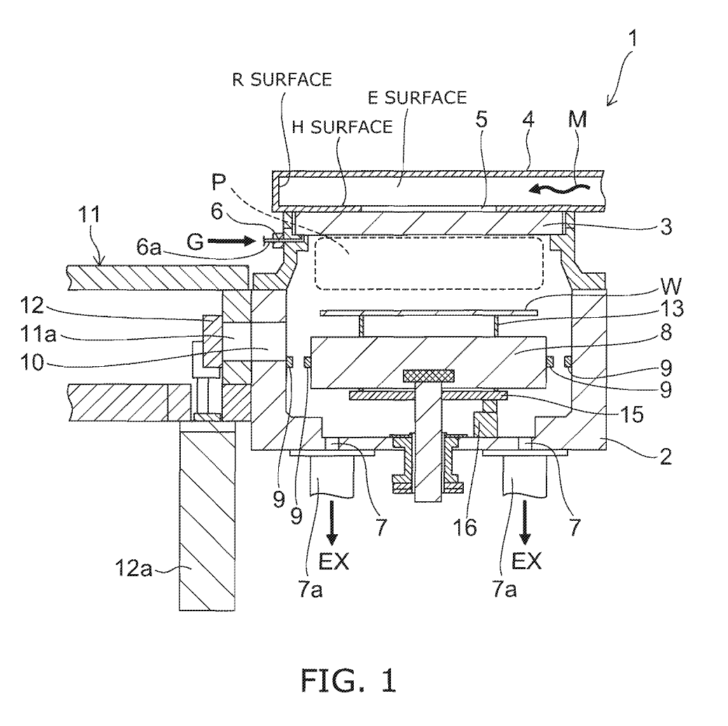

FIG. 1 is a schematic view illustrating a plasma processing apparatus according to an embodiment of the invention.

As illustrated in FIG. 1, a processing container 2 having a substantially cylindrical configuration is provided in the plasma processing apparatus 1. The processing container 2 is capable of maintaining an atmosphere having a pressure lower than atmospheric pressure. The processing container 2 is formed of a metal material such as stainless steel, aluminum alloy, etc.

An opening is provided in an upper portion of the processing container 2; and a dielectric window 3 is provided in the opening. The dielectric window 3 is formed of a dielectric material such as quartz glass or alumina. A not-illustrated sealing member such as an O-ring is provided between the dielectric window 3 and the opening of the processing container 2; and airtightness can be maintained.

A waveguide 4 is provided in an upper portion of the processing container 2 including the dielectric window 3. The cross section of the waveguide 4 has a rectangular configuration. A surface (an H surface) opposing the dielectric window 3 forms a surface perpendicular to an electric field direction of a microwave M. A surface (an E surface) extending in a direction perpendicular to the H surface forms a surface parallel to the electric field direction of the microwave; and a surface provided on a propagation side of the microwave M perpendicular to the H surface and the E surface forms a reflective surface (a short surface; an R surface). A slot (an antenna unit) 5 is made in the H surface along the E surface. A not-illustrated microwave production unit is connected to the waveguide 4; and the microwave M produced by the not-illustrated microwave production unit can be wave-guided by the waveguide 4. In this embodiment, the slot 5 forms a microwave introduction unit that introduces the microwave M to the interior of the processing container 2.

A gas inlet 6 is provided in a side wall upper portion of the processing container 2 and is connected to a not-illustrated gas introduction unit via a pipe 6a. A process gas G supplied from the not-illustrated gas introduction unit is introduced to the interior of the processing container 2 via the pipe 6a. The gas inlet 6 is provided at a position where the process gas G can be introduced toward a generation region of a plasma P positioned below the dielectric window 3.

The process gas G may be appropriately selected according to the type of the plasma processing, etc. For example, simple oxygen gas (O₂) or a gas mixture of a fluorine-containing gas such as CF₄, NF₃, SF₆, etc., added to oxygen gas, a gas in which hydrogen gas is added to such gases, etc., may be used in the case where etching of an object W to be processed is performed. The process gas G is not limited to such examples and can be modified appropriately.

An evacuation port 7 is provided in a bottom surface of the processing container 2. A not-illustrated evacuation unit is connected to the evacuation port 7 via an evacuation pipe 7a. The not-illustrated evacuation unit of a vacuum pump, etc., can reduce the pressure of the interior of the processing container to a prescribed pressure. Further, a not-illustrated open/shut valve, a not-illustrated pressure control valve such as an APC valve, etc., may be provided appropriately between the evacuation port 7 and the not-illustrated evacuation unit. Then, an atmosphere can be provided and maintained with a pressure less than atmospheric pressure by controlling the not-illustrated evacuation unit, open/shut valve, pressure control valve, etc., to perform an evacuation EX of the interior of the processing container 2.

A receive/dispatch port 10 is provided in a side wall of the processing container 2 for transferring the object W to be processed into and out of the processing container 2 interior. A load lock chamber 11 is provided to oppose the receive/dispatch port 10. In the load lock chamber 11, an opening 11a is provided to communicate with the receive/dispatch port 10; and a gate valve 12 that can airtightly stop the opening 11a is provided. Also, an open/close unit 12a that opens and closes the opening 11a by causing the gate valve 12 to ascend and descend is provided.

A placement platform 8 is provided in the interior of the processing container 2. A not-illustrated electrostatic chuck and/or a not-illustrated heating unit such as a heater are built into the placement platform 8. The object W to be processed placed on an upper surface of the placement platform 8 can be held by the not-illustrated electrostatic chuck. Also, the object W to be processed can be heated by the not-illustrated heating unit.

A flow regulation plate 9 is provided in an outer circumference of the placement platform 8 below the upper surface of the placement platform 8. Many holes are provided in the flow regulation plate 9. The flow regulation plate 9 controls the flow of gas at the surface of the object W to be processed by controlling the flow of gas evacuated from the surface of the object W to be processed.

A through-hole is multiply provided to insert lifter pins 13 through the placement platform 8; and the lifter pins 13 are extendable and retractable from the upper surface of the placement platform 8. Then, the upper end faces of the multiple lifter pins 13 protruding from the upper surface of the placement platform 8 can support the back surface of the object W to be processed. In other words, the lifter pin can be ascendably and descendably inserted through the placement platform 8 provided in the interior of the processing container 2; and the end surface of the lifter pin can support the back surface of the object W to be processed. A lower end of the lifter pin 13 is held in an ascending/descending plate 15. Also, an ascending/descending unit 16 is connected to the ascending/descending plate 15; and the ascending/descending plate 15 can be caused to ascend and descend. Therefore, the lifter pin 13 can be caused to extend and retract from the upper surface of the placement platform 8 by the ascending/descending unit 16 causing the ascending/descending plate 15 to ascend and descend.

A not-illustrated control unit is provided in the plasma processing apparatus 1 and can control operations, processing times, etc., of the components provided in the plasma processing apparatus 1. For example, the ascent/descent of the lifter pin 13, the introduction of the process gas G and the microwave M, the pressure of the processing container 2 interior, the temperature of the placement platform 8, etc., can be controlled.

Here, the processing of both surfaces of the object W to be processed can be performed simultaneously by causing the lifter pin 13 to protrude from the upper surface of the placement platform 8 and by lifting the object W to be processed from the upper surface of the placement platform 8. Further, the temperature of the object W to be processed can be controlled by causing the object W to be processed to ascend and descend and by changing the distance between the placement platform 8 and the object W to be processed.

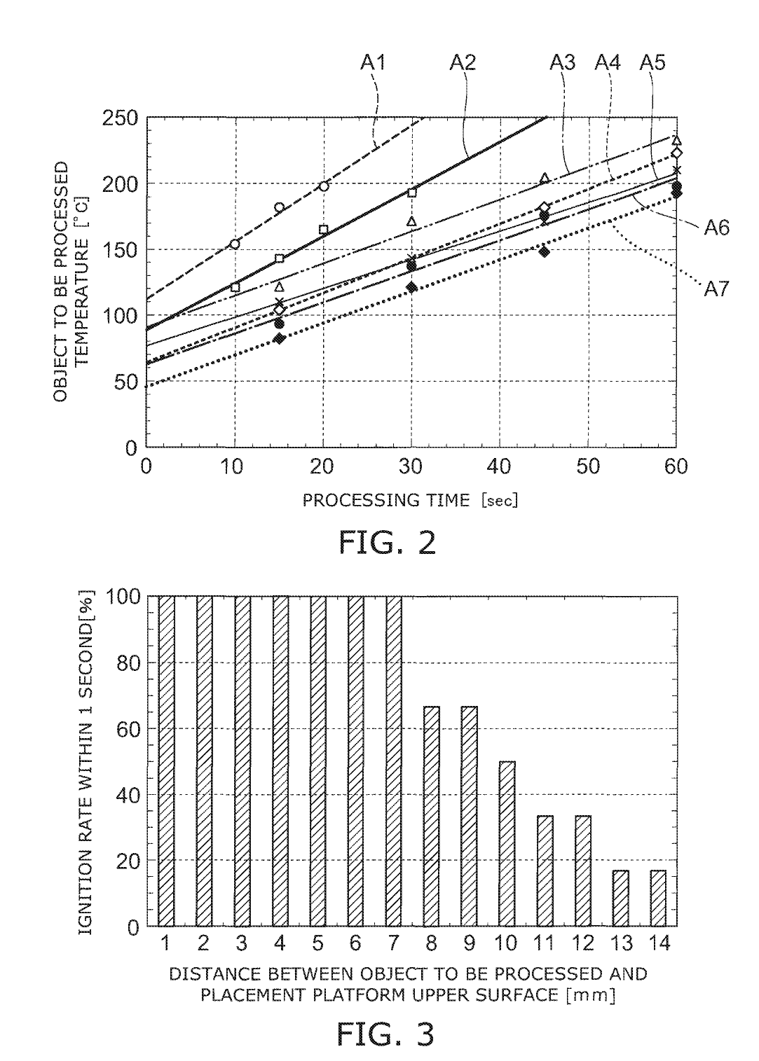

FIG. 2 is a graph illustrating the relationship between the lift amount and the temperature of the object to be processed. The temperature of the object W to be processed is plotted on the vertical axis; and the processing time is plotted on the horizontal axis. A1 is the case where the lift amount is 0 mm (the state of being placed on the upper surface of the placement platform 8); A2 is the case of 1 mm; A3 is the case of 2 mm; A4 is the case of 3 mm; A5 is the case of 4 mm; A6 is the case of 5 mm; and A7 is the case of 23 mm. In such a case, the processing conditions include using a process gas G of a gas mixture of fluorine-containing gas and oxygen gas, a processing pressure of 120 Pa, a microwave output of 2700 W, and a placement platform temperature of 275° C.

As illustrated in FIG. 2, the temperature increase of the object W to be processed can be suppressed because the heat amount received from the heating unit provided in the placement platform 8 decreases as the lift amount of the object W to be processed increases. Therefore, it is possible to perform the temperature control of the object W to be processed by the position (the lift amount) of the object W to be processed. Thus, compared to the case where the temperature control is performed by the heating unit provided in the placement platform 8, the temperature control can be performed with a high responsivity and processing is possible at a low temperature.

For example, the case where ashing processing is performed on a resist having an altered layer formed on the surface may be illustrated as a case where the object W to be processed is lifted from the upper surface of the placement platform 8 by the lifter pin 13 and plasma processing is performed.

In the case where ashing processing is performed on the resist having the altered layer formed on the surface, there is a risk that popping may occur in the case where the temperature of the object W to be processed increases too much. Therefore, the ashing processing may be performed at a position (a lift amount) where the temperature is such that popping does not occur.

Here, the generation of the plasma P may be obstructed in the case where the lift amount of the object W to be processed is increased too much. In other words, in some cases, the ignition of the plasma P cannot be performed and the plasma P cannot be generated.

According to knowledge obtained by the inventor, the ignition of the plasma P is obstructed because the microwave M introduced into the processing container 2 is absorbed by the object W to be processed in the case where the object W to be processed and the placement platform 8 become too distal to each other (the case where the lift amount is increased too much). In such a case, the microwave M being absorbed by the object W to be processed also causes the temperature of the object W to be processed to increase. As a result, not only is the temperature controllability of the object W to be processed obstructed, but also there is a risk that deformation, damage, etc., of the object W to be processed due to heat may occur.

On the other hand, in the case where the lift amount is reduced too much, there is a risk that the heat amount received from the heating unit provided in the placement platform 8 may increase, the temperature of the object W to be processed may increase, and the popping and the like described above may undesirably occur because the distance between the object W to be processed and the placement platform 8 decreases.

Therefore, in this embodiment, the position (the lift amount) of the object W to be processed is changed between the position during the ignition of the plasma P and the position during the plasma processing. In other words, the object W to be processed is supported by the lifter pin 13 at a position proximal to the upper surface of the placement platform 8 when performing the ignition of the plasma P by introducing the microwave M; and after the ignition of the plasma P, the object W to be processed is supported by the lifter pin 13 at a position more distal to the placement platform 8 than the position described above, i.e., a position proximal to the plasma P side.

Thus, during the ignition of the plasma P, it is possible to realize a reliable ignition of the plasma P, and an unnecessary temperature increase can be suppressed by reducing the absorption amount of the microwave M by the object W to be processed.

Also, the controllability of the plasma processing can be increased by lifting the object W to be processed to a position more proximal to the generated plasma P, i.e., a position suited to the plasma processing, after the ignition of the plasma P.

As described below, after the ignition of the plasma P, the microwave M is reflected in a space up to a constant distance (a skin depth) from the lower surface of the dielectric window 3; and a standing wave of the microwave M is formed. Then, the reflective surface of the microwave M becomes a plasma excitation surface; and the stable plasma P is excited by the plasma excitation surface. Therefore, there is little effect on the generation of the plasma P even in the case where the object W to be processed is moved to a position more proximal to the generated plasma P by lifting the object W to be processed.

FIG. 3 is a graph illustrating the relationship between the lift amount of the object W to be processed and the ignition rate of the plasma. The ignition rate within 1 second (the probability that ignition can be performed within 1 second) is plotted on the vertical axis; and the distance between the back surface of the object W to be processed and the placement platform 8 upper surface (the lift amount of the object W to be processed) is plotted on the horizontal axis.

As illustrated in FIG. 3, a reliable ignition can be performed in the case where the distance between the back surface of the object W to be processed and the placement platform 8 upper surface (the lift amount of the object W to be processed) is not more than 7 mm. In such a case, more heat is received from the heating unit provided in the placement platform 8 as the distance between the back surface of the object W to be processed and the placement platform 8 upper surface decreases (as the lift amount of the object W to be processed decreases). Therefore, to suppress an unnecessary temperature increase, it is favorable for the distance between the back surface of the object W to be processed and the placement platform 8 upper surface (the lift amount of the object W to be processed) to be not less than 1 mm. In other words, it is favorable for the position to be where the end surface of the lifter pin protrudes not less than 1 mm and not more than 7 mm from the upper surface of the placement platform 8.

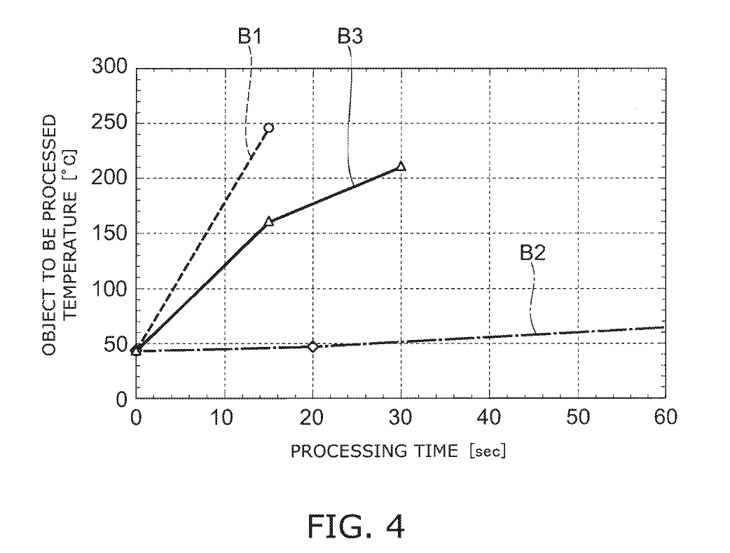

FIG. 4 is a graph illustrating the temperature of the object to be processed during the plasma processing. The temperature of the object to be processed is plotted on the vertical axis; and the processing time is plotted on the horizontal axis. B1 is the case where the distance between the back surface of the object W to be processed and the placement platform 8 upper surface is 23 mm and the ignition of the plasma P and the plasma processing are performed at this position. B2 is the case where the distance between the back surface of the object W to be processed and the placement platform 8 upper surface is left at a position of 23 mm without performing the plasma processing. B3 is the case where the object W to be processed is supported proximally to the upper surface of the placement platform 8 during the ignition of the plasma P; and the object W to be processed is lifted to a position suited to the plasma processing after the ignition of the plasma P. In other words, B3 is the case where the distance between the back surface of the object W to be processed and the placement platform 8 upper surface is 4 mm during the ignition of the plasma P and the distance between the back surface of the object W to be processed and the placement platform 8 upper surface is 23 mm after the ignition of the plasma P. In such a case, the processing conditions include using a process gas G of a gas mixture of fluorine-containing gas and oxygen gas, a processing pressure of 20 Pa, a microwave output of 2700 W, and a placement platform temperature of 275° C.

In the case of B2, the temperature of the object W to be processed increases only due to the heat from the heating unit provided in the placement platform 8 because of being left without performing the plasma processing. In such a case, the temperature increase due to the heat from the heating unit provided in the placement platform 8 can be substantially eliminated in the case where the distance between the back surface of the object W to be processed and the placement platform 8 upper surface is 23 mm. Thus, the thermal effect from the not-illustrated heating unit provided in the placement platform 8 can be suppressed in the case where the distance between the back surface of the object W to be processed and the placement platform 8 upper surface (the lift amount of the object W to be processed) is increased a certain amount.

In the case of B1, the microwave M is absorbed by the object W to be processed and the temperature of the object W to be processed increases because the back surface of the object W to be processed and the placement platform 8 are too distal to each other during the ignition as well. Because there is little thermal effect from the heating unit provided in the placement platform 8 as illustrated by B2, the temperature increase in the case of B1 is due to the absorption of the microwave M. While it is difficult to ignite the plasma P in the case where the back surface of the object W to be processed and the placement platform 8 upper surface are too distal to each other during the ignition, the temperature increase due to the heat from the plasma P additionally occurs in the case where the plasma P is ignited.

In the case of B3, the amount of the microwave M absorbed by the object W to be processed is suppressed because the distance between the back surface of the object W to be processed and the placement platform 8 upper surface is small during the ignition. In such a case, there is a high possibility of the plasma P being ignited; and the temperature increase of the object W to be processed is mainly due to the heat from the plasma P.

Thus, the unintended temperature increase of the object W to be processed can be suppressed by supporting the object W to be processed at a position proximal to the upper surface of the placement platform 8 when performing the ignition of the plasma P and by lifting the object W to be processed to a position suited to the plasma processing after the ignition of the plasma P. Further, the ignition rate of the plasma can be increased and the controllability of the plasma processing can be increased.

It is favorable for the position of the object W to be processed after the ignition of the plasma P to be a position where the thermal effect from the not-illustrated heating unit provided in the placement platform 8 is suppressed. Thus, the deformation and the damage of the object W to be processed can be suppressed. Also, it is favorable for the position to be where the popping of the resist is suppressed in the case where ashing processing is performed on a resist having an altered layer formed on the surface.

Effects of the plasma processing apparatus 1 will now be illustrated.

First, the object W to be processed is transferred into the interior of the processing container 2 via the load lock chamber 11 by a not-illustrated transfer unit. After delivering the transferred object W to be processed to the upper end surface of the lifter pin 13, the not-illustrated transfer unit retreats out of the processing container 2. Subsequently, the processing container 2 is sealed airtightly by the gate valve 12.

The pressure of the interior of the airtightly sealed processing container 2 is reduced to a prescribed pressure by a not-illustrated evacuation unit while a prescribed process gas G is introduced. Subsequently, the microwave M is introduced to the dielectric window 3 via the slot 5. The microwave M propagates through the surface of the dielectric window 3 and is radiated into the processing space inside the processing container 2. Thus, the plasma P of the process gas G forms due to the energy of the microwave M radiated into the processing space. When the electron density in the plasma P becomes equal to or greater than the density (the cutoff density) at which the microwave M introduced by passing through the dielectric window 3 can be screened, the microwave M is reflected in a space up to the constant distance (the skin depth) from the lower surface of the dielectric window 3. Therefore, a standing wave of the microwave M is formed.

Then, the reflective surface of the microwave M becomes a plasma excitation surface; and the plasma P is stably excited by the plasma excitation surface. Excited active species (plasma products) such as atoms, molecules, free atoms (radicals), etc., excited by ions and electrons impacting molecules of the process gas G are produced in the stable plasma P excited by the plasma excitation surface. Various plasma processing such as etching, ashing, thin film deposition, surface modification, plasma doping, etc., may be performed by such plasma products diffusing downward through the processing container 2 to project to the surface of the object W to be processed.

The object W to be processed for which the plasma processing is completed is transferred out of the processing container 2 via the load lock chamber 11. Thereafter, the plasma processing may be performed similarly for other objects W to be processed.

Here, a plasma processing method according to this embodiment illustrated below can be implemented in the plasma processing apparatus 1.

In the plasma processing method according to this embodiment, the position (the lift amount) of the object W to be processed is changed between the position during the ignition of the plasma P and the position during the plasma processing.

First, as described above, the object W to be processed is delivered to the upper end surface of the lifter pin 13 and is supported. Then, the pressure of the interior of the processing container 2 is reduced to a prescribed pressure less than atmospheric pressure; and a prescribed process gas G is introduced.

Then, the object W to be processed is supported proximally to the upper surface of the placement platform 8 by lowering the lifter pin 13.

Continuing, the plasma P is initiated (ignited) by introducing the microwave M to the dielectric window 3 via the slot 5 and radiating the microwave M propagating through the surface of the dielectric window 3 into the processing space. At this time, a reliable ignition can be realized because the amount of the microwave M absorbed by the object W to be processed can be reduced by the object W to be processed being supported proximally to the upper surface of the placement platform 8. Also, for the same reason, the unintended unnecessary temperature increase can be suppressed. In such a case, as described above, it is favorable for the end surface of the lifter pin to protrude to a position not less than 1 mm and not more than 7 mm from the upper surface of the placement platform 8.

After the plasma P is ignited, the object W to be processed is lifted to a position suited to the plasma processing. In other words, after the ignition of the plasma P, the object W to be processed is supported by the lifter pin 13 at a position more proximal to the plasma side than is the position described above. Thus, it is possible to increase the controllability of the plasma processing such as increasing the processing speed, increasing the uniformity in the processing surface, etc. Further, the deformation and the damage of the object W to be processed is suppressed because the thermal effect from the not-illustrated heating unit provided in the placement platform is suppressed. Moreover, the popping of the resist is suppressed in the case where ashing processing is performed on a resist having an altered layer formed in the surface. While the ascent/descent control of the lifter pin 13 is performed as described above by a not-illustrated control unit, the ignition of the plasma may be performed, for example, by sensing a light emission of the plasma by a sensor and by controlling using a time determined from an experiment (time control).

Next, a method for manufacturing an electronic device according to this embodiment of the invention will now be illustrated.

For convenience of the description, an example is illustrated in which the method for manufacturing the electronic device according to this embodiment of the invention is a method for manufacturing a semiconductor apparatus.

The method for manufacturing the semiconductor apparatus is implemented by repeating multiple processes such as the processes that form patterns on a substrate (wafer) surface by film formation, resist coating, exposing, developing, etching, resist removal, etc., the inspection processes, cleaning processes, heat treatment processes, impurity introduction processes, diffusion processes, planarizing processes, etc.

Then, for example, the semiconductor apparatus can be manufactured by using the plasma processing apparatus 1 according to this embodiment to form a pattern on the substrate surface and by removing the resist. Also, for example, the semiconductor apparatus can be manufactured using the plasma processing method according to this embodiment by forming the pattern on the substrate surface and removing the resist.

By using the plasma processing apparatus and the plasma processing method according to this embodiment, an increase of the productivity can be realized and an increase of the product quality also can be realized.

Other than the plasma processing apparatus and the plasma processing method according to this embodiment, known technology of the processes can be applied, and therefore a description thereof is omitted.

Although the method for manufacturing the semiconductor apparatus is illustrated as the method for manufacturing the electronic device according to this embodiment of the invention for convenience of the description, the invention is not limited thereto. For example, applications are possible also in the manufacturing of liquid crystal display apparatuses, the manufacturing of fuel cells, the manufacturing of solar cells, and the manufacturing of other various electronic parts and the like.

Although the plasma processing apparatus 1 is illustrated using a surface wave plasma, the invention is not limited thereto. Applications are possible to various plasma processing apparatuses in which plasma is generated by introducing a microwave to the interior of a processing container. Moreover, applications are possible not only to etching processing and ashing processing but also to surface modification processing and the like.

Hereinabove, exemplary embodiments of the invention are illustrated. However, the invention is not limited to these descriptions.

Appropriate design modifications made by one skilled in the art in regard to the embodiments described above also are within the scope of the invention to the extent that the features of the invention are included.

For example, the configurations, dimensions, material qualities, dispositions, etc., of the components included in the plasma processing apparatus 1 are not limited to those illustrated and may be modified appropriately.

Further, the components included in the embodiments described above may be combined within the extent of feasibility, and such combinations also are within the scope of the invention to the extent that the features of the invention are included.

### INDUSTRIAL APPLICABILITY

As described above in detail, the invention can provide a plasma processing apparatus, a plasma processing method, and a method for manufacturing an electronic device that can increase the ignition rate of plasma.

### EXPLANATION OF REFERENCE

1 plasma processing apparatus
2 processing container
3 dielectric window
4 waveguide
8 placement platform
13 lifter pin
G process gas
M microwave
P plasma
W object to be processed

What is claimed is:

1. A plasma processing apparatus, comprising:
a processing container capable of maintaining an atmosphere having a pressure lower than atmospheric pressure;
an evacuation unit reducing a pressure of an interior of the processing container;
a gas introduction unit introducing a process gas to the interior of the processing container;
a microwave introduction unit introducing a microwave to the interior of the processing container; and
a lifter pin ascendably and descendably inserted through a placement platform provided in the interior of the processing container, an end surface of the lifter pin supporting an object to be processed,
the object to be processed being supported by the lifter pin at a first position proximal to an upper surface of the placement platform when the microwave is introduced and plasma is ignited,
the object to be processed being supported by the lifter pin at a second position after the plasma ignition, the second position being more distal to the placement platform than the first position.

2. The plasma processing apparatus according to claim 1, wherein the first position is a position where the end surface of the lifter pin protrudes not less than 1 mm and not more than 7 mm from the upper surface of the placement platform.

3. The plasma processing apparatus according to claim 1, further comprising
a heating unit provided in the placement platform,
the second position being a position where a thermal effect from the heating unit is suppressed.

4. The plasma processing apparatus according to claim 3, wherein the position where the thermal effect is suppressed is a position where popping of a resist provided in the object to be processed is suppressed.

5. A plasma processing method, comprising:
supporting an object to be processed by an end surface of a lifter pin ascendably and descendably inserted through a placement platform provided in an interior of a processing container;
reducing a pressure of the interior of the processing container to less than atmospheric pressure;
introducing a process gas to the interior of the processing container, introducing a microwave to the interior of the processing container, and initiating plasma; and
performing a plasma processing of the object to be processed,
the object to be processed being supported by the lifter pin at a first position proximal to an upper surface of the placement platform when igniting the plasma,
the object to be processed being supported by the lifter pin at a second position after the plasma ignition, the second position being more distal to the placement platform than the first position.

6. The plasma processing method according to claim 5, wherein the first position is a position where the end surface of the lifter pin protrudes not less than 1 mm and not more than 7 mm from the upper surface of the placement platform.

7. The plasma processing method according to either of claim 5, wherein the second position is a position where a thermal effect from the heating unit provided in the placement platform is suppressed.

8. The plasma processing method according to claim 7, wherein the position where the thermal effect is suppressed is a position where popping of a resist provided in the object to be processed is suppressed.

9. A method for manufacturing an electronic device by performing a plasma processing of an object to be processed by using the plasma processing apparatus according to claim 1.
